(19) United States
(12) Patent Application Publication
(10) Pub. No.: US 2010/0134066 A1
(43) Pub. Date: Jun. 3, 2010

(54) PORTABLE ELECTRONIC DEVICE

(75) Inventors: ZHI-ZHONG XIAO, ShenZhen City (CN); JUAN-RONG WU, ShenZhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/422,359

(22) Filed: Apr. 13, 2009

(30) Foreign Application Priority Data
Dec. 1, 2008 (CN) 200810305881.2

(51) Int. Cl. H02J 7/00; H01L 41/00

(52) U.S. Cl. 320/107; 310/319

(57) ABSTRACT

A portable electronic device includes a control module, a battery and a charging module. The battery electrically connects with the control module to supply the power. The charging module includes an electric energy generating body and a bump body. The electric energy generating body is made of piezoelectric material. The bump body is movably assembled within the charging module to impact and deform the electric energy generating body to generating electric energy. The charging module is electrically connected with the battery to charge the battery.

### BACKGROUND

1. Technical Field

The exemplary disclosure generally relates to a portable electronic device, and particularly to a portable electronic device with self-charging function.

2. Description of Related Art

With the development of wireless communication and information processing technologies, portable electronic devices such as mobile phones and personal digital assistants (PDAs) are now in widespread use, and consumers may now enjoy the full convenience of high technology products almost anytime and anywhere.

The conventional portable electronic device usually includes a battery assembled therein to supply power. However, during usage, the battery is easily run down. Therefore, people often need to charge the battery using a charging device or replace the battery. When people take part in outdoor activities and forget to take along extra batteries, if the batteries in the portable electronic device run down, the portable electronic device will become inoperative and inconvenience its owner.

Therefore, there is room for improvement within the art.

### BRIEF DESCRIPTION OF THE DRAWINGS

Many aspects of the present portable electronic device can be better understood with reference to the following drawings. The components in the drawings are not necessarily drawn to scale, the emphasis instead being placed upon clearly illustrating the principles of the present portable electronic device. Moreover, in the drawings, like reference numerals designate corresponding parts throughout the several views.

FIG. 1 shows a block diagram of a portable electronic device, in accordance with an exemplary embodiment of the present invention.

FIG. 2 shows a circuit diagram of the portable electronic device in FIG. 1.

### DETAILED DESCRIPTION

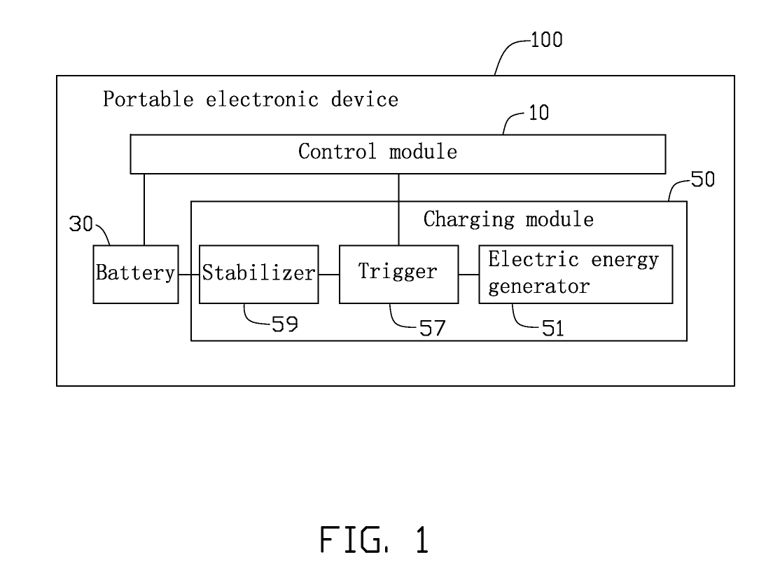

FIG. 1 shows a block diagram of a portable electronic device 100, in accordance with an exemplary embodiment of the present invention. The portable electronic device 100 includes a control module 10, a battery 30 and a charging module 50.

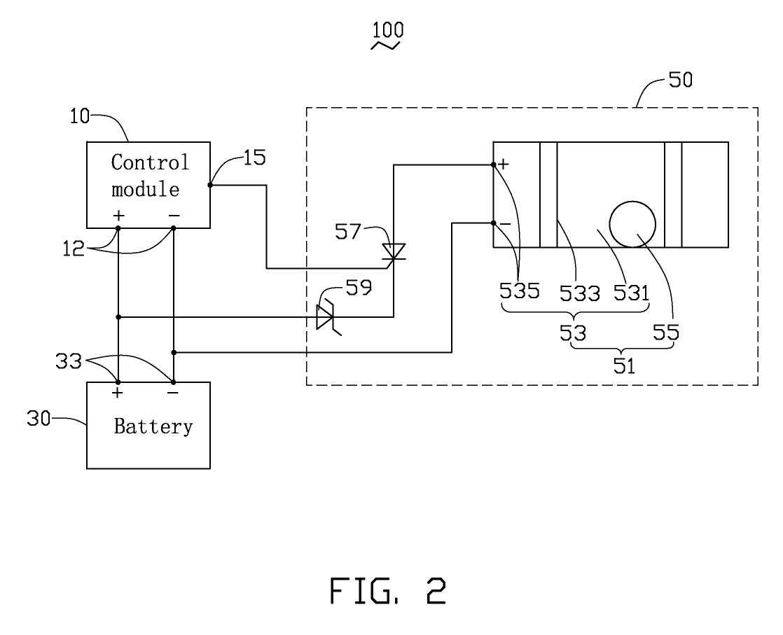

Referring to FIG. 2, the control module 10 is assembled within a circuit board of the portable electronic device 100, and includes two power input ports 12, and a signal triggering port 15. The two power input ports 12 includes a positive pole and a negative pole that electrically connect with the battery 30, so that the control module 10 can receive power energy and detect a power energy status, e.g., a voltage value of the battery 30 therethrough. The control module 10 determines whether or not to send out a triggering signal based on the received energy status of the battery 30. When the control module 10 detects that the voltage value of the battery 30 is lower than a low threshold voltage value, the control module 10 sends out the triggering signal to the charging module 50 so that the charging module 50 begins to charge the battery 30. When the control module 10 detects that the voltage value of the battery 30 is higher than a high threshold voltage value, the control module 10 stops sending out the triggering signal to the charging module 50, so that the charging module 50 stops charging the battery 30. The signal triggering port 15 electrically connects with the charging module 50, so that the control module 10 can send out the triggering signal to the charging module 50 therethrough. The signal triggering port 15 outputs a low voltage signal, e.g., a zero volt voltage, in default. When the signal triggering port 15 changes to output a high voltage, it means that the control module 10 sends out a triggering signal.

The battery 30 includes two electrodes 33 with a positive electrode and a negative electrode disposed thereon that corresponding to the two power input ports 12 of the control module 10. The two electrodes 33 electrically connect with the two power input ports 12 respectively.

The charging module 50 electrically connects with the battery 30 and the signal triggering port 15 of the control module 10. The charging module 50 starts or stops to charge the battery 30 in response to the triggering signal transmitting from the control module 10. The charging module 50 includes an electric energy generator 51, a trigger 57 and a stabilizer 59 connected in series. The electric energy generator 51 includes an electric energy generating body 53 and a bump body 55. The electric energy generating body 53 is made of piezoelectric material such as piezoelectric ceramic. When the electric energy generating body 53 is bumped by an outer force, the surface of the electric energy generating body 53 will be deformed to generate electric energy. The electric energy generating body 53 is a tube body with a closed chamber 531 formed therein to accommodate the bump body 55. The chamber 531 includes a bump surface 533 within the electric energy generating body 53. The electric energy generating body 53 includes two power output ports 535 configured to output the electric power generated by the electric energy generating body 53.

The bump body 55 is movably assembled within the chamber 531 of the electric energy generating body 53 to impact the bump surface 533 of the chamber 531. And thereby the bump surface 533 deforms to generating electric energy, when people take along or move the portable electronic device 100.

The trigger 57 is a switching diode having an anode, a cathode and a controlling port. The anode, the cathode and the controlling port electrically connect with the electric energy generator 51, stabilizer 59 and the signal triggering port 15 of the control module 10 respectively. The trigger 57 is disconnected or not working when the received triggering signal sent through the signal triggering port 15 is a low voltage signal. When the voltage value of the battery 30 is lower than the low threshold voltage value, the signal triggering port 15 outputs a high voltage which means a triggering signal is sent to the charging module 50. And thereby the trigger 57 is activated which means there is current flowing from the charging module 50 to the battery 30, and thus the battery 30 is charged by the charging module 50.

The stabilizer 59 is a voltage stabilizing diode which is electrically connected between the cathode of the trigger 57 and the positive electrode of the battery 30. The stabilizer 59 is used to protect the battery 30 and the control module 10 to avoid being damaged.

When people operate the portable electronic device 100 or take along the portable electronic device 100 running, sporting etc., the bump body 55 moving within the chamber 531 of the electric energy generating body 53 to impact the bump surface 533 of the chamber 531 and make the bump surface 533 deform to generating electric energy.

It is understood that the charging module 50 could further include an energy storing device such as accumulator which is used to store the electric energy generated by the electric energy generator 51.

It is understood that the shape of the bump body 55 could be different types. In the present embodiment, the bump body 55 is a ball. The chamber 531 is substantially tube sphere shape according to the present embodiment.

It is to be understood, however, that even though numerous characteristics and advantages of the present invention have been set forth in the foregoing description, with details of the structure and function of the present invention, the disclosure is illustrative only, and changes may be made in detail, especially in matters of shape, size, and arrangement of parts within the principles of present invention to the full extent indicated by the broad general meaning of the terms in which the appported claims are expressed.

What is claimed is:

1. A portable electronic device comprising:
a control module;
a battery assembled within the portable electronic device that electrically connecting with the control module to supply power; and
a charging module comprising an electric energy generator that electrically connecting with the battery to charge the battery, the electric energy generator comprising:
an electric energy generating body made of piezoelectric material; and
a bump body movably assembled within the electric energy generating body to impact and deform the electric energy generating body to generating electric energy.

2. The portable electronic device as claimed in claim 1, wherein the control module including a signal triggering port disposed thereon that electrically connects with the charging module, the control module being used to receive power energy and detect the power energy status of the battery for determining whether or not to send out a triggering signal to the charging module to drive the charging device charge the battery.

3. The portable electronic device as claimed in claim 2, wherein the signal triggering port outputs a low voltage signal in default, when the voltage value of the battery is lower than the low threshold voltage value, the control module sends out a high voltage signal to the charging module to charge the battery.

4. The portable electronic device as claimed in claim 3, wherein the charging module further includes a trigger electrically connecting with the signal triggering port of the control module and the electric energy generator; the trigger not working when the received triggering signal sent through the signal triggering port is a low voltage signal.

5. The portable electronic device as claimed in claim 4, wherein the trigger is a switching diode having an anode, a cathode and a controlling port that electrically connect with the electric energy generator, the battery and the signal triggering port of the control module respectively.

6. The portable electronic device as claimed in claim 5, wherein the charging module further includes a stabilizer electrically connected between the cathode of the trigger and the battery to protect the battery and the control module.

7. The portable electronic device as claimed in claim 6, wherein the stabilizer is a voltage stabilizing diode.

8. The portable electronic device as claimed in claim 6, wherein the electric energy generating body is made of piezoelectric ceramic and is a tube body with a closed chamber formed therein to accommodate the bump body; the chamber includes a bump surface contact with the bump body.

9. The portable electronic device as claimed in claim 8, wherein the electric energy generating body includes two power output ports thereon to output the electric power generated by the electric energy generating body.

10. The portable electronic device as claimed in claim 8, wherein the bump body is a ball, the chamber is tube sphere shape.

11. A portable electronic device comprising:
a battery assembled within the portable electronic device to supply electric power; and
a charging module comprising an electric energy generator that electrically connects with the battery to charge the battery, the electric energy generator comprising:
an electric energy generating body made of piezoelectric material; and
a bump body movably assembled within the electric energy generating body to impact and deform the electric energy generating body to generating electric energy.

12. The portable electronic device as claimed in claim 11, wherein the portable electronic device further comprising a control module assembled within a circuit board, the control module including two power input ports electrically connect with the battery and a signal triggering port electrically connects with the charging module, the control module is used to receive power energy and detect the power energy status of the battery for determining whether or not to send out a triggering signal to the charging module to drive the charging device charge the battery.

13. The portable electronic device as claimed in claim 12, wherein the charging module further includes a trigger electrically connecting with the signal triggering port of the control module and the electric energy generator; the trigger not working when the received triggering signal sent through the signal triggering port is a low voltage signal.

14. The portable electronic device as claimed in claim 13, wherein the trigger is a switching diode having an anode, a cathode and a controlling port that electrically connect with the electric energy generator, the battery and the signal triggering port of the control module respectively.

15. The portable electronic device as claimed in claim 13, wherein the charging module further includes a stabilizer electrically connected between the cathode of the trigger and the battery to protect the battery and the control module.

16. The portable electronic device as claimed in claim 15, wherein the stabilizer is a voltage stabilizing diode.

17. The portable electronic device as claimed in claim 16, wherein the electric energy generating body is made of piezoelectric ceramic and is a tube body with a closed chamber formed therein to accommodate the bump body; the chamber includes a bump surface contact with the bump body.

18. The portable electronic device as claimed in claim 17, wherein the electric energy generating body includes two power output ports thereon to output the electric power generated by the electric energy generating body.
